(19) United States
(12) Patent Application Publication
(10) Pub. No.: US 2008/0174030 A1
(43) Pub. Date: Jul. 24, 2008

(54) Multichip stacking structure

(75) Inventors: Chung-Lun Liu, Taichung (TW); Chin-Huang Chang, Taichung (TW); Yi-Feng Chang, Taichung (TW); Jung-Pin Huang, Taichung (TW); Chih-Ming Huang, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/009,865

(22) Filed: Jan. 23, 2008

(30) Foreign Application Priority Data
Jan. 24, 2007 (TW) 096102616
Dec. 17, 2007 (TW) 096148169

(51) Int. Cl. H01L 23/492

(52) U.S. Cl. 257/777; 257/E23.026

(57) ABSTRACT

The present invention provides a multi-chip stacking structure. The multichip stacking structure comprises: a chip carrier; a first and a second chip modules respectively having a plurality of first and a plurality of second chips, wherein each chips has a bond pad and the chips are stacked on the chip carrier in a step-like manner to expose the bond pads; and a plurality of bonding wires for electrically connecting the bond pads of the first and the second chip modules to the chip carrier, wherein a bottom chip of the second chip module is stacked on a top chip of the first chip module by an adhesive layer having fillers therein to support the bottom chip, and the bottom chip is deviated from the top chip horizontally in a direction toward the bonding wires of the first chip module.

### BACKGROUND OF THE INVENTION

1. Field of the Invention

The present invention relates to a semiconductor package, and more particularly to a multichip stacking structure.

2. Description of the Prior Art

Due to development of the electronic industry, techniques relating to miniaturization and high operational speed for electronic devices are desirable. In such demand, semiconductor packages have evolved gradually to increase the electrical functionality and capability in a single semiconductor package, and multichip module has become a popular trend to be adopted in the fabrication of semiconductor packages. Multichip module is a technology to assemble two or more semiconductor chips in a single package, so as to reduce the overall size of the circuit structure in an electronic product, and to improve electrical functionality. In other words, with the capability to assemble two or more chips in a single semiconductor package, the multichip structures effectively increase the system operational speed. Moreover, multichip structures can reduce the connection length between each chip so as to reduce the signal delay and to save time.

A side-by-side method is commonly adopted by the multichip structure, in which more than two chips are disposed side-by-side on a main mounting surface of a carrier. The electrical connection between such chips and circuits on the carrier is established through a wire bonding method. However, as the number of the chips in such side-by-side multichip module increase, the main mounting surface of the carrier is increased accordingly, which further results in the undesirable high packaging cost and relatively large package size.

In order to solve the foregoing drawbacks of the prior art, in recent years an upright stacking technique is adopted to stack chips, and the stacking of chips has some variation according to the design of the chip and the wire bonding process. However, if the chips are designed to have bond pads concentrated on one side, such as flash memory chips, a step-like stacking must be performed for the convenience of wire bondings. For example, as shown in FIG. 1A, a multichip stacking structure disclosed in U.S. Pat. No. 6,621,155 is formed by stacking a plurality of chips on a chip carrier 10 in such a way that a first chip 11 is disposed on the chip carrier 10 while a second chip 12 is stacked on the first chip 11 as being deviated from the first chip 11 for a distance and without affecting the wire bonding of the bond pad to the first chip 11. A third chip 13 is stacked on the second chip 12 in such a way that it is deviated from the second chip 12 without affecting the wire bondings of the bond pad to the first and the second chips 11, 12.

Such multichip stacking structure can reduce the required mounting area in comparison with side-by-side method, and is also advantageous for performing chip stacking before wire bonding. However, due to such stacking technique deposing the chips deviated from the previous one towards one direction, such staking structure is disadvantageous in that the projection area of the whole stacking chip module is enlarged as the number of the stacking chips is increased. As shown in FIG. 1B, assuming a side length of each of semiconductor chips 11, 12, 13, 14 is S, and a distance of each of the chips 12, 13, 14 deviated from a lower layered chip 11, 12, 13 thereof (if there is any) is L, then after n chips are stacked, a projection length of whole stacking chip module is S+(n−1)L. As shown, when continuously stacking chips in a step-like manner towards one direction on a chip carrier 10, a certain chip, for example the chip 14, would exceed the packaging size, thus size of the chip carrier 10 is required to be enlarged to finish the chip stacking. Such enlarged package area thus would affect the size of the overall electronic product, which is away from today's demand of miniaturization and multi-functionality for electronic products.

Please refer to FIG. 2, which is a schematic view showing a multichip staking structure disclosed in T.W. Patent No. 1255492. The multichip staking structure comprises: a chip carrier 20; a first chip module 21 having a plurality of chips 211, 212, each of which is disposed with a bond pad on one side; bonding wires 241 for electrically connecting the chips 211, 212 to the chip carrier 20; a buffering element 23 disposed on the first chip module 21; a second chip module 22 having a plurality of chips 223, 224 disposed with bond pads on one side; and bonding wires 242 for electrically connecting the chips 223, 224 to the chip carrier 20. The chips 211, 212 are stacked on the chip carrier 20 in a step-like manner, and the chip 223 at the bottom of the second chip module 22 is mounted on the buffering element 23 in such a way that it is shifted toward the bond pad of the first chip module 21. The remaining chip 224 is then stacked in a step-like manner. As a result, the problem that all chips are sequentially shifted to one side can be alleviated and thereby increasing the number of chips that can be stacked within a certain packaging area.

However, such multichip stacking structure still possesses a few drawbacks. First, an extra process for deposing the buffering element is required for stacking chips, thereby increasing the fabrication cost and fabricating steps. Moreover, due to the deposition of the buffering layer, the height of such multichip stacking structure cannot be effectively reduced, which is unfavorable to the fabrication of low-profile electronic device (such as Micro-SD card).

Thus, there is an urgent need to develop a multichip stacking structure, which allows multiple chips to be packaged within a single package without additionally increasing the package area and height for low-profile electronic products and also gives good considerations for reducing processing steps and fabrication cost.

### SUMMARY OF THE INVENTION

In light of the foregoing drawbacks of the prior art, a primary objective of the present invention is to provide a multichip stacking structure for stacking multiple chips without additional increasing package area and height.

Another objective of the present invention is to provide a multichip stacking structure for a low-profile electronic device.

Yet another objective of the present invention is to provide a semiconductor package with reduced fabricating cost and steps in chip stacking.

In order to achieve the foregoing and other objectives, the present invention provides a multichip stacking structure, which comprises: a chip carrier; a first chip module having a plurality of first chips, wherein each of the first chips has a first bond pad deposed at an edge of a surface thereof and the first chips are stacked on the chip carrier in a step-like manner to expose the first bond pads; a plurality of first bonding wires for electrically connecting the first chip bond pads to the chip carrier; a second chip module having a plurality of second chips, wherein each of the second chips has a second bond pad deposed at an edge of a surface thereof and the second chips are stacked on the first chip module in the step-like manner to expose the second bond pads, a bottom chip of the second chip module is stacked on a top chip of the first chip module by an adhesive layer having fillers therein to support the bottom chip, and the bottom chip is deviated from the top chip horizontally in a direction toward the first bonding wires connected to the first chip module; and a plurality of second bonding wires for electrically connecting the second bond pads of the second chip module to the chip carrier.

In addition, the multichip stacking structure further comprises an encapsulant, which is deposed on the chip carrier for encapsulating the first and the second chip modules and the first and second bonding wires. Preferably, the projection of the second chip module is within (i.e. does not exceed) the projection of the first chip module. In addition, the first and second chip modules are electrically connected to the chip carrier by a general wire bonding method or reverse wire bond method, in which the reverse wire bond method allows an outer end of the bonding wire to be bonded to the chip carrier prior bonding an inner end of the bonding wire to the chip, so as to reduce the height of the wire loop, which further reduces the thickness of the adhesive layer or the adhesive film, thereby permitting a smaller and more light-weighted multichip stacking structure.

Each of the plurality of chips in the first and second chip modules has the bond pad thereof to be deposed on a single side of the respective modules. The chips are stacked in the mentioned step-like manner, which means that each upper one is shifted horizontally a predetermined distance in respective to the respective one therebeneath, i.e. away from the edges deposed with the bond pads. That is to say, the chips stacked in such way prevents the chip stacking from blocking a space vertically above the bond pads of the chip underneath, and favoring the wire bonding process to electrically connect the chips to the chip carrier by the plurality of bonding wires.

The multichip stacking structure of another preferred embodiment of the present invention comprises: a chip carrier; a first chip module having a plurality of first chips, wherein each of the first chips has a first bond pad deposed at an edge of a surface thereof and the first chips are stacked on the chip carrier in a step-like manner to expose the first bond pads; a plurality of first bonding wires for electrically connecting the first chip bond pads to the chip carrier; a second chip module having a plurality of second chips, wherein each of the second chips has a second bond pad deposed at an edge of a surface thereof and the second chips are stacked on the first chip module in the step-like manner to expose the second bond pads, a bottom chip of the second chip module is stacked on a top chip of the first chip module by an adhesive film deposed therebetween, a portion of the first bonding wire between the bottom chip of the second chip module and the top chip of the first chip module is covered by the adhesive film, and the bottom chip is deviated from the top chip horizontally in a direction toward the first bonding wires connected to the first chip module; and a plurality of second bonding wires for electrically connecting the second bond pads of the second chip module to the chip carrier. In addition, the multichip stacking structure further comprises an encapsulant deposed on the chip carrier for encapsulating the first and the second chip modules, and the first and the second bonding wires.

Furthermore, still another embodiment of the multichip stacking structure is provided. The multichip stacking structure comprises: a chip carrier; a first chip module having a plurality of first chips stacked on the chip carrier in a step-like manner; a plurality of first bonding wires for electrically connecting the first chip module to the chip carrier; a second chip module having at least one second chip and mounted on the first chip module, wherein a bottom chip of the second chip module is stacked on a top chip of the first chip module by an adhesive layer having fillers therein to support the bottom chip; and a plurality of second bonding wires for electrically connecting the second chip module to the chip carrier. In addition, the multichip stacking structure further comprises an encapsulant deposed on the chip carrier for encapsulating the first and the second chip modules, and the first and the second bonding wires, and the second chip module is in position to or deviated a predetermined distance from a top chip of the first chip module.

In yet another embodiment of the present invention, a multichip stacking structure comprises: a chip carrier; a first chip module having a plurality of first chips stacked on the chip carrier in a step-like manner; a plurality of first bonding wires for electrically connecting the first chip module to the chip carrier; a second chip module having at least one second chip and mounted on the first chip module by an adhesive film disposed between the second chip module and a top chip of the first chip module, wherein a portion of first bonding wires between the second chip module and the top chip of the first chip module is covered by the adhesive film; and a plurality of second bonding wires for electrically connecting the second chip module to the chip carrier. In addition, the multichip stacking structure further comprises an encapsulant deposed on the chip carrier for encapsulating the first and the second chip modules and the first and the second bonding wires, and the formation of the second chip module is performed by steps of: providing at least one chip with a non-conductive adhesive layer pre-adhered to a surface thereof; and pressing the at least one chip on the first chip module and covering one of the first bounding wire of a top chip of the first chip module. Furthermore, the second chip module is in position to or deviated a predetermined distance from a top chip of the first chip module.

Thus, according to the multichip stacking structure of the invention, the multiple chips each having the bond pad disposed on one side are sequentially stacked on the chip carrier in a step-like manner to form a first chip module. Then a plurality of first bonding wires are used to electrically connect the first chip module to the chip carrier. The numbers of chips to be stacked can be up to the maximum that can be packaged on the carrier. Then, the bottom chip of the second chip module is deposed on the top chip of the first chip module by the adhesive layer having fillers therein for support the bottom chip or the adhesive film for covering the portion of the first bonding wire between the bottom chip of the second chip module and the top chip of the first chip module in a way that the bottom chip is deviated from the top chip horizontally in a direction toward the first bonding wires connected to the first chip module. Then remaining chips for the second chip module are stacked on the bottom chip in a manner as the stacking process for stacking chips of the first chip module. In such way, the problem that all chips deposed towards one direction is prevented and as a result more chips can be stacked. Moreover, the additional costs and fabrication steps for the additional deposing of buffering element in the prior art can be also eliminated. The multiple stacking structure provided by the present invention thus provides a solution to perform multiple chip stacking free from increasing package area and height, and is suitable for a light-weighted, small and low profile electronic device.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a schematic cross-sectional view showing a multichip stacking structure disclosed in U.S. Pat. No. 6,621,155;

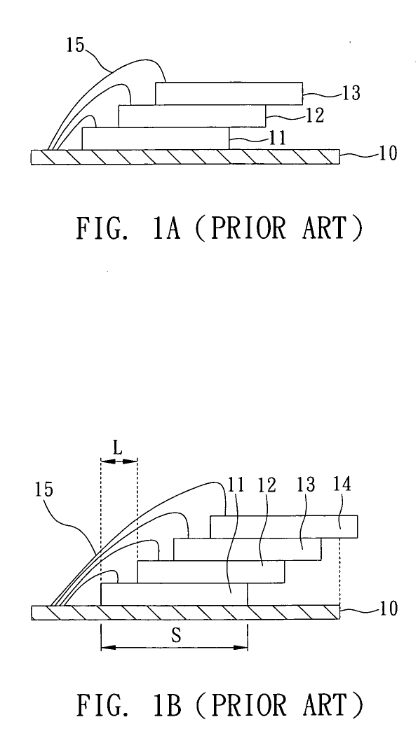

FIGS. 1B (PRIOR ART) is a schematic view showing drawbacks of a conventional multichip stacking structure stacked by a step-like stacking method toward a single direction;

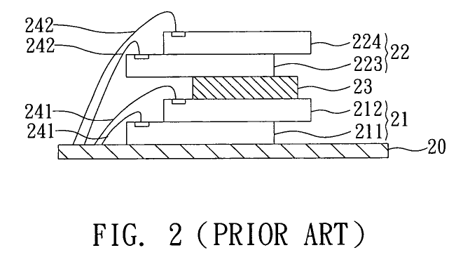

FIGS. 2 (PRIOR ART) is a schematic cross-sectional view showing a multichip stacking structure disclosed in T.W. Patent No. 1255492;

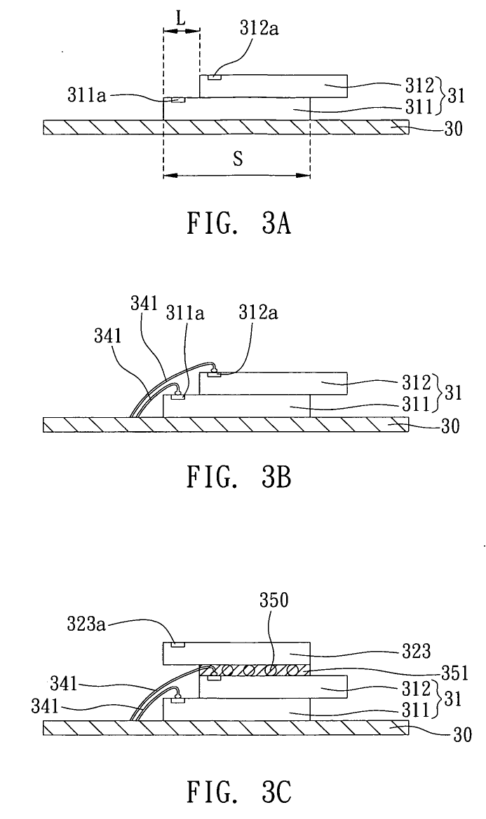

FIGS. 3A to 3F are schematic cross-sectional views showing a multichip stacking structure and a fabrication method thereof according to a first preferred embodiment of the present invention;

FIGS. 4A to 4F are schematic views showing a multichip stacking structure and a fabrication method thereof according to a second preferred embodiment of the present invention;

FIG. 5 is a schematic view showing a multichip stacking structure and a fabrication method thereof according to a third preferred embodiment of the present invention;

FIG. 6 is a schematic view showing a multichip stacking structure and a fabrication method thereof according to a fourth preferred embodiment of the present invention;

FIGS. 7A and 7B are schematic views showing a multichip stacking structure and a fabrication method thereof according to a fifth preferred embodiment of the present invention.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

### First Preferred Embodiment

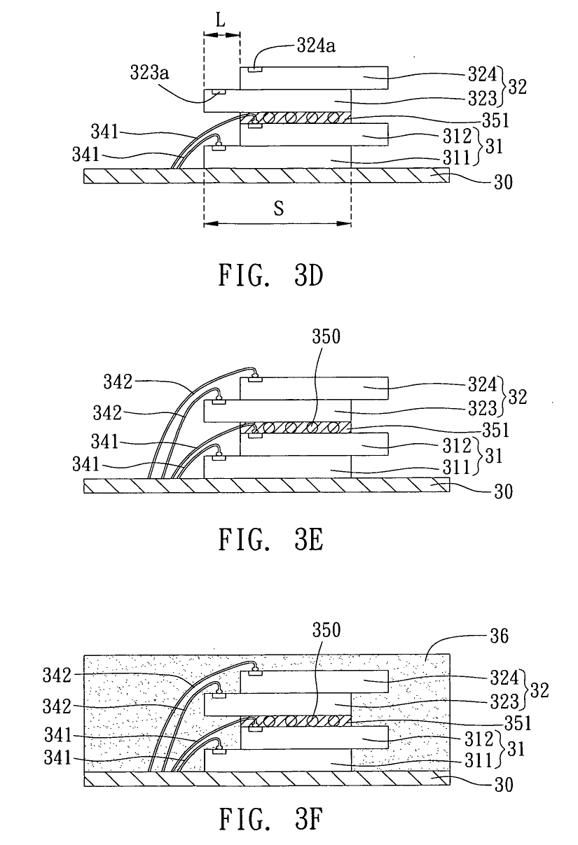

Referring to FIGS. 3A to 3F, which are cross-sectional views of a multichip stacking structure and a fabrication method thereof according to a first preferred embodiment of the present invention.

As shown in FIG. 3A, a chip carrier 30 and a plurality of chips 311 and 312, are provided, and the chip 311 and the chip 312 respectively has a bond pad 311a, 312a disposed at edges of surfaces thereof. After the chip 311 is attached to the chip carrier 30 by an adhesive such as conductive or non-conductive adhesive (not shown), and the chip 312 is attached to the chip 311 in a step-like manner to expose the bond pad 311a of the chip 311, thereby a first chip module 31 is formed. The chip carrier 30 can be a ball grid array (BGA) substrate, a land grid array (LGA) substrate or a lead frame.

As shown in FIG. 3B, a plurality of first bonding wires 341 are used to electrically connect the bond pads 311a, 312a of the chips 311 and 312 of the first chip module 31 to the chip carrier 30.

In the present embodiment, the first chip module 31 comprises the chips 311 and 312 (not limited to two chips), wherein the chips 311 and 312 are approximate in size with a side length thereof being S, and have the bond pads 311a, 312a on respective single sides thereof. The chip 312 is shifted a predetermined distance L away from the bond pad 311a of the chip 311, so that a space vertically above the bond pad 311a would not be blocked by the chip 312, which allows to perform the wire bonding process to electrically connect the chips 311 and 312 to the chip carrier 30 by the first bonding wires 341.

As shown in FIG. 3C, a chip 323 having a bond pad 323a at an edge of a surface thereof is disposed on a top chip (i.e. the chip 312) of the first chip module 31 with a non-conductive adhesive layer 351 mounted therebetween, wherein the chip 323 is deviated from the chip 312 horizontally in a direction toward the first bonding wires 341. The adhesive layer 351 has a plurality of fillers 350 deposed therein so as to provide physical support to the chip 323, and to prevent the chip 323 from damaging the first bonding wires 341.

Please refer to FIGS. 3D and 3E, subsequently, a chip 324 is attached to the chip 323 in a step-like manner to expose the bond pad 323a of the chip 323, so as to form a second chip module 32. Then, a plurality of second bonding wires 342 are used to electrically connect the bond pads 323a, 324a of the chips 323 and 324 of the second chip module 32 to the chip carrier 30.

In the embodiment, the second chip module 32 comprises the chips 323 and 324 (not limited to two chips), which have the bond pad 323a and a bond pad 324a respectively on respective single sides thereof. The chip 324 is horizontally shifted a predetermined distance L away from the bond pad 323a of the chip 323, so that the space vertically above the bond pad 323a would not be blocked by the chip 324, which allowing to perform the wire bonding process to electrically connect the chips 323 and 324 to the chip carrier 30 by the second bonding wires 342.

A preferable deposition position of the chip 323 of the second chip module 32 is a position that a projection of the chip 323 is corresponding to a position of the chip 311 of the first chip module 31. Similarly, a preferable deposition position of the chip 324 stacked on the chip 323 is a position that a projection of the chip 324 is corresponding to a position of the chip 312. In such way, regardless of how many stacking layers there are, the overall projection length of the stacking structure should remain as (S+L). Comparing with the increased projection length as a result of conventional step-like stacking with the chips shifted toward a single direction, the overall projected length of the stacking structure of the present embodiment of the invention is 2L less than the above-mentioned one in the prior art.

It should be noted that since the bottom chip (i.e. the chip 323) of the second chip module 32 is mounted on the top chip (i.e. the chip 312) in such a way that the chip 323 is deviated from the chip 312 horizontally in the direction toward the first bonding wires 341 of the first chip module 31, and the chip 324 is stacked on the chip 323 in a way as the stacking of the first chip module 31, the chips 311 and 312 and the chips 323 and 324 of the first and the second chip modules 31 and 32 respectively are not all stacked continuously toward a single direction. Hence, this embodiment prevents the package with multichip from problems such as a large area of the chip carrier being occupied by the stacked chips and the stacking structure exceeding the maximal available size to be packaged. Moreover, since the chip 323 is mounted to the chip 312 by an adhesive layer 351 having fillers 350 filled therein, the present invention is also free from the problem in the prior art that a stacking height cannot be effectively reduced due to the use of buffering element. Preferably, the fillers 350 are made of insulation materials, or metal particles covered by an insulation film.

As shown in FIG. 3F, an encapsulant 36 is then deposed on the chip carrier 30 to encapsulate the first chip module 31, the second chip module 32, the first bonding wires 341 and the second bonding wires 342.

Through the foregoing fabrication method, the multichip stacking structure disclosed in the present invention comprises: the chip carrier 30; the first chip module 31 having the plurality of first chips 311 and 312, wherein the first chips 311 and 312 respectively have bond pads 311a and 312a deposed at edges of surfaces thereof and the first chips 311 and 312 are stacked on the chip carrier 30 in a step-like manner to expose the bond pads 311a and 312a; the plurality of first bonding wires 341 for electrically connecting the bond pads 311a and 312a to the chip carrier 30; the second chip module 32 having the plurality of second chips 323 and 324, wherein the second chips 323 and 324 respectively have bond pads 323a and 324a deposed at edges of surface thereof, and the second chips 323 and 324 are stacked on the first chip module 31 to expose the bond pads 323a and 324a, the bottom chip (i.e. the chip 323) of the second chip module 32 is stacked on the top chip (i.e. the chip 312) of the first chip module 31 by the adhesive layer 351 having fillers 350 therein to support the chip 323, and the chip 323 is deviated from the chip 312 horizontally in a direction toward the first bonding wires 341 connected to the first chip module 31; the plurality of second bonding wires 342 for electrically connecting the bond pads 323a and 324a of the second chip module 32 to the chip carrier 30; and the encapsulant 36 deposed on the chip carrier 30 for encapsulating the first and the second chip modules 31 and 32 and the first and the second bonding wires 341 and 342.

### Second Preferred Embodiment

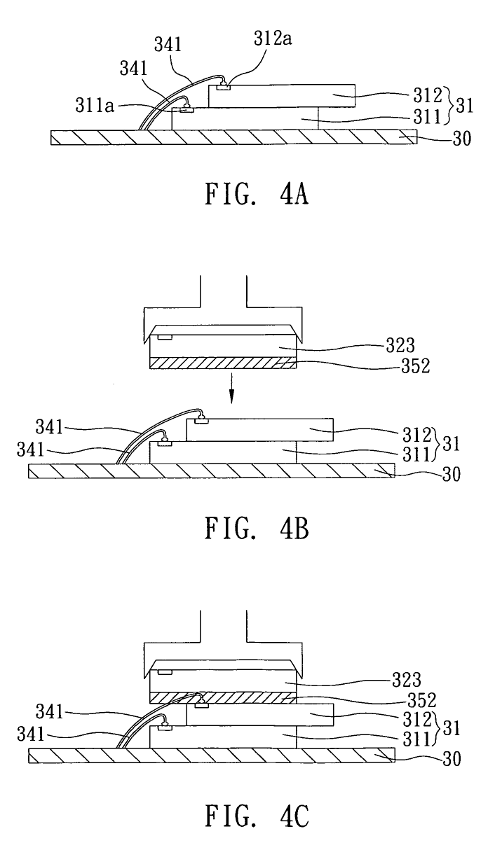

Referring to further FIGS. 4A to 4F, which are schematic views of a multichip stacking structure and a fabrication method thereof according to a second preferred embodiment of the present invention. The second embodiment is similar to the first embodiment, except that the bottom chip of the second chip module of the second embodiment is mounted on the top chip of the first chip module by a film over wire (FOW) technology while the bottom chip of the second chip module of the first embodiment is mounted on the top chip of the first chip module by the adhesive layer mounted therebetween (as shown in FIG. 3F). The corresponding or equivalent elements in this embodiment and the first embodiment will be described with the same reference numeral.

As shown in FIG. 4A, a chip carrier 30 and a plurality of chips 311, 312 are provided, and these chips 311, 312 have respectively a bond pads 311a and 312a on edges of surfaces thereof. The chips 311 and 312 are mounted on the chip carrier 30 in a step-like manner to expose the bond pads 311a, 312a, so as to form a first chip module 31. The chips 311 and 312 are electrically connected to the chip carrier 30 by a plurality of first bonding wires 341.

As shown in FIGS. 4B and 4C, by using a non-conductive film 352, which is attached to one side of a chip 323 having a bond pad 323a at an edge of a surface thereof previously, the chip 323 is directly pressed onto a top surface of the chip 312 of the first chip module 31, which allows the film 352 to cover a portion of the first boning wire 341 between the chip 323, and the chip 312 of the first chip module 31.

As shown in FIGS. 4D and 4E, a chip 324 having a bond pad 324a at an edge of a surface thereof is mounted to the chip 323 in a step-like manner to expose the bond pad 323a of the chip 323, so as to form a second chip module 32. A plurality of second bonding wires 342 are used to electrically connect the bond pads 323a, 324a of the chips 323 and 324 of the second chip module 32 to the chip carrier 30.

As shown in FIG. 4F, subsequently, an encapsulant 36 is formed on the chip carrier 30 to encapsulate the first chip module 31, the second chip module 32, the first bonding wires 341, and the second bonding wires 342.

Through the foregoing fabrication method, a multichip stacking structure disclosed in the present invention comprises: the chip carrier 30, the first chip module 31 having the plurality of first chips 311 and 312, wherein the first chips 311 and 312 respectively have bond pads 311a and 312a deposed at edges of surfaces thereof and the first chips 311 and 312 are stacked on the chip carrier 30 in the step-like manner to expose the bond pads 311a and 312a; the plurality of first bonding wires 341 for electrically connecting the bond pads 311a and 312a to the chip carrier 30; the second chip module 32 having the plurality of second chips 323 and 324, wherein the second chips 323 and 324 respectively have bond pads 323a and 324a deposed at edges of surface thereof, and the second chips 323 and 324 are stacked on the first chip module 31 to expose the bond pads 323a and 324a, the bottom chip (i.e. the chip 323) of the second chip module 32 is stacked on a top chip (i.e. the chip 312) of the first chip module 31 by the adhesive film 352 mounted therebetween, where the portion of the first bonding wire connected to the chip 312 between the chips 312 and 323 are covered by the adhesive film 352, and the chip 323 is deviated from the chip 312 horizontally in a direction toward the first bonding wires 341 connected to the first chip module 31; the plurality of second bonding wires 342 for electrically connecting the second bond pads 323a and 324a of the second chip module 32 to the chip carrier 30, and the encapsulant 36 deposed on the chip carrier 30 for encapsulating the first and the second chip modules 31 and 32 and the first and the second bonding wires 341 and 342.

### Third Preferred Embodiment

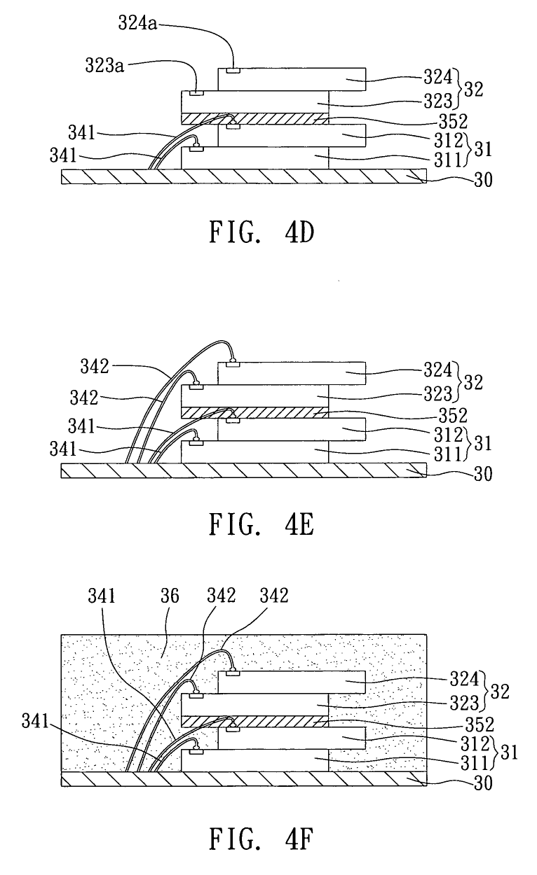

Referring to further FIG. 5, which is a schematic view of a multichip stacking structure and a fabrication method thereof according to a third preferred embodiment of the present invention. The present embodiment is similar to the foregoing embodiments except that the top chip of the first chip module of the third embodiment is electrically connected to the chip carrier by reverse wire bond technology, so as to further reduce the overall height of the stacking structure while the foregoing embodiments using a conventional wire bonding technology. The corresponding or equivalent elements in this embodiment and the forgoing embodiments will be described with the same reference numeral.

As shown in the FIG. 5, a chip 312 of a first chip module 31 is bonded to the chip carrier 30 by a reverse wire bond technology. In the reverse wire bond technology, an outer end of a bonding wire 341 connected to the chip 312 is firstly bonded to a bond pad 312a of the chip 312 to form a stud (not shown), followed by being bonded with the chip carrier 30, pulling upward to bond with the stud, thereby stitch bonding the bonding wire 341 to the stud of the bond pad 312a of the chip 312. In such way, the loop height of the bonding wire for electrically connecting between the chip 312 and a chip carrier 30 is reduced, and as a result a thickness of an adhesive film 352 required for mounting a second chip module 32 to a first chip module 31 is reduced, thereby further reducing the height of the overall stacking structure.

In addition, a chip 311 of the first chip module 31 can be electrically connected to the chip carrier 30 by the first bonding wires 341 using a conventional wire bonding method or a reverse wire bond method.

### Fourth Preferred Embodiment

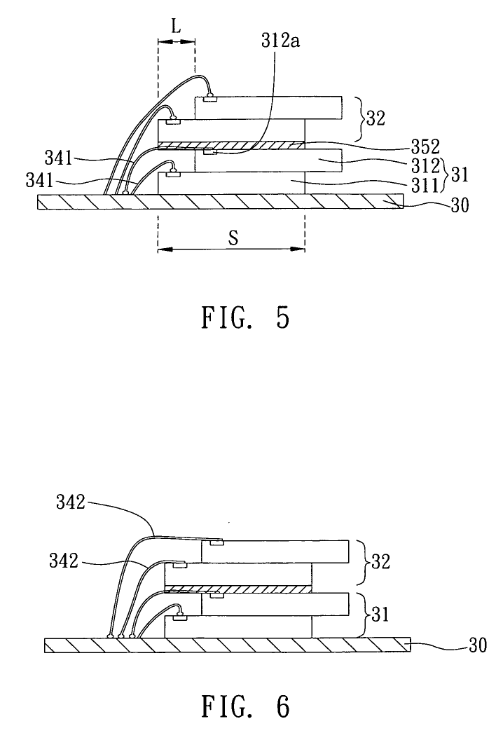

Referring to further FIG. 6, which is a schematic view of a multichip stacking structure and a fabrication method thereof according to a fourth preferred embodiment of the present invention. The present embodiment is similar to the foregoing embodiments except that a second chip module 32 in the fourth embodiment can be electrically connected to a chip carrier 30 through second bonding wires 342 by optionally using a reverse wire bond method.

In addition, both a first and a second chip modules 31 and 32 are not limited to have only two chips. If n chips are to be stacked, the sum of the total projected length of the chips should still remain (S+L). As compared to the sum of the total projection length of S+(n−1)L in the conventional technology in which the plurality of chips are stacked toward a single direction, the total projection length of the chips in the stacking structure of the present invention is (S+(n−1)L)−(S+L)=(n−2)L less.

Moreover, a third chip module can be also stacked on the second chip module. Similarly, it is achieved by deposing the bottom chip of the third chip module on the top chip of the second chip module in a horizontal direction towards the second bonding wires by an adhesive layer or film.

### Fifth Preferred Embodiment

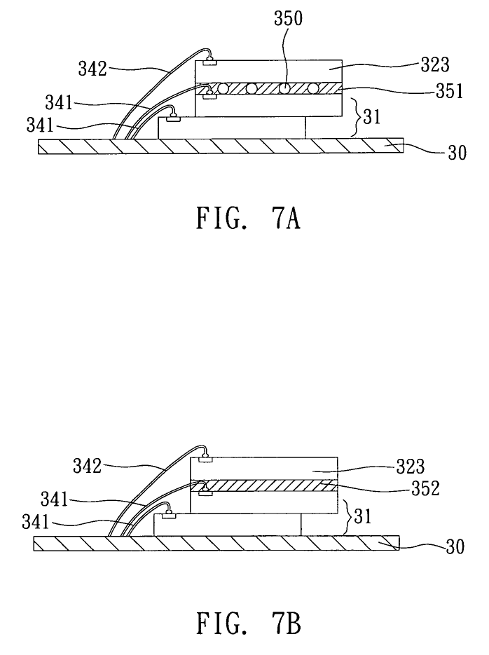

Referring to further FIGS. 7A and 7B, which are schematic views of a multichip stacking structure and a fabrication method thereof according to a fifth preferred embodiment of the present invention.

The present embodiment is similar to the foregoing embodiments except that a first chip module 31 is mounted on a chip carrier 30 and a plurality of first bonding wires 341 is used for electrically connecting the first chip module 31 to the chip carrier 30 before that a second chip module having at least one chip 323 is mounted on the first chip module 31 by an adhesive layer 351 having fillers 350 therein to support the chip 323 (as shown in FIG. 7A) or by directly pressing the chip 323, which has a non-conductive adhesive film 352 previously adhered on the bottom side thereof to first chip module 31 to cover a portion of the first bonding wires 341 between the chip 323 and the top chip of the first chip module 31 (as shown in FIG. 7B), thereby preventing from damaging the first bonding wires 341. In addition, the second bonding wires 342 are electrically connected between the chip 323 and the chip carrier 30 subsequently, and the chip 323 is in position to or deviated a predetermined distance from the top chip of the first chip module 31.

Thus, according to the multichip stacking structure and the fabrication method thereof of the invention, the multiple chips each having the bond pad disposed on one side are sequentially stacked on the chip carrier in a step-like manner to form a first chip module. Then a plurality of first bonding wires are used to electrically connect the first chip module to the chip carrier. The numbers of chips to be stacked can be allowed to up to the maximal size that can be packaged. Then, the bottom chip of the second chip module is deposed on the top chip of the first chip module by the adhesive layer having filters therein for support the bottom chip or the adhesive film for covering the portion of the first bonding wire of the top chip. Then the remaining chips for the second chip module are stacked on the bottom chip in a step-like manner as the stacking process for stacking chips of the first chip module. In such way, the problem that all chips deposed toward one direction continuously is prevented and as a result more chips can be stacked. Moreover, the additional costs and fabrication steps for the additional deposing of buffering element in the prior art can be also eliminated. The multiple stacking structure provided by the present invention thus provides a solution to proceed multiple chip stacking without the need to increase package area and height, and is suitable for a lightweight, small and low profile electronic device.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A multichip stacking structure, comprising
a chip carrier;
a first chip module having a plurality of first chips, wherein each of the first chips has a first bond pad deposed at an edge of a surface thereof and the first chips are stacked on the chip carrier in a step-like manner to expose the first bond pads;
a plurality of first bonding wires for electrically connecting the first chip bond pads to the chip carrier;
a second chip module having a plurality of second chips, wherein each of the second chips has a second bond pad deposed at an edge of a surface thereof and the second chips are stacked on the first chip module in the step-like manner to expose the second bond pads, a bottom chip of the second chip module is stacked on a top chip of the first chip module by an adhesive layer having fillers therein to support the bottom chip, and the bottom chip is deviated from the top chip horizontally in a direction toward the first bonding wires connected to the first chip module; and
a plurality of second bonding wires for electrically connecting the second bond pads of the second chip module to the chip carrier.

2. The multichip stacking structure of claim 1, wherein the projection of the second chip module is within that of the first chip module.

3. The multichip stacking structure of claim 1, further comprising an encapsulant deposed on the chip carrier for encapsulating the first and the second chip modules and the first and the second bonding wires.

4. The multichip stacking structure of claim 1, wherein projections of the second chips are corresponding to positions of the first chips.

5. The multichip stacking structure of claim 1, further comprising a third chip module stacked on the second chip module.

6. The multichip stacking structure of claim 1, wherein the top chip of the first chip module is electrically connected to the chip carrier by a reverse wire bond method.

7. The multichip stacking structure of claim 1, wherein the first and the second chip modules are electrically connected to the chip carrier by one of a wire bonding method and a reverse wire bond method.

8. A multichip stacking structure, comprising
a chip carrier;
a first chip module having a plurality of first chips, wherein each of the first chips has a first bond pad deposed at an edge of a surface thereof and the first chips are stacked on the chip carrier in a step-like manner to expose the first bond pads;
a plurality of first bonding wires for electrically connecting the first chip bond pads to the chip carrier;
a second chip module having a plurality of second chips, wherein each of the second chips has a second bond pad deposed at an edge of a surface thereof and the second chips are stacked in the step-like manner on the first chip module to expose the second bond pads, a bottom chip of the second chip module is stacked on a top chip of the first chip module by an adhesive film, a portion of the first bonding wire between the bottom chip of the second chip module and the top chip of the first chip module is covered by the adhesive film, and the bottom chip is deviated from the top chip horizontally in a direction toward the first bonding wires connected to the first chip module; and
a plurality of second bonding wires for electrically connecting the second bond pads of the second chip module to the chip carrier.

9. The multichip stacking structure of claim 8, wherein the projection of the second chip module is within that of the first chip module.

10. The multichip stacking structure of claim 8, further comprising an encapsulant deposed on the chip carrier for encapsulating the first and the second chip modules and the first and the second bonding wires.

11. The multichip stacking structure of claim 8, wherein projections of the second chips are corresponding to positions of first chips.

12. The multichip stacking structure of claim 8, further comprising a third chip module stacked on the second chip module.

13. The multichip stacking structure of claim 8, wherein the top chip of the first chip module is electrically connected to the chip carrier by a reverse wire bond method.

14. The multichip stacking structure of claim 8, wherein the first and the second chip modules are electrically connected to the chip carrier by one of a wire bonding method and a reverse wire bond method.

15. A multichip stacking structure, comprising
a chip carrier;
a first chip module having a plurality of first chips stacked on the chip carrier in a step-like manner;
a plurality of first bonding wires for electrically connecting the first chip module to the chip carrier;
a second chip module having at least one second chip and mounted on the first chip module, wherein a bottom chip of the second chip module is stacked on a top chip of the first chip module by an adhesive layer having fillers therein to support the bottom chip; and
a plurality of second bonding wires for electrically connecting the second chip module to the chip carrier.

16. The multichip stacking structure of claim 15, wherein the projection of the second chip module is within that of the first chip module.

17. The multichip stacking structure of claim 15, further comprising an encapsulant deposed on the chip carrier for encapsulating the first and the second chip modules and the first and the second bonding wires.

18. The multichip stacking structure of claim 15, wherein projections of the second chips are corresponding to positions of the first chips.

19. The multichip stacking structure of claim 15, further comprising a third chip module stacked on the second chip module.

20. The multichip stacking structure of claim 15, wherein the first and the second chip modules are electrically connected to the chip carrier by one of a wire bonding method and a reverse wire bond method.

21. The multichip stacking structure of claim 15, wherein the bottom chip of the second chip module is in one of a position corresponding to that of the top chip of the first chip module and a position horizontally deviated from that of the top chip of the first chip module for a distance.

22. A multichip stacking structure, comprising
a chip carrier;
a first chip module having a plurality of first chips stacked on the chip carrier in a step-like manner;
a plurality of first bonding wires for electrically connecting the first chip module to the chip carrier;
a second chip module having at least one second chip and mounted on the first chip module by an adhesive film disposed between the second chip module and a top chip of the first chip module, wherein a portion of first bonding wires between the second chip module and the top chip of the first chip module is covered by the adhesive film; and
a plurality of second bonding wires for electrically connecting the second chip module to the chip carrier.

23. The multichip stacking structure of claim 22, wherein the projection of the second chip module is within that of the first chip module.

24. The multichip stacking structure of claim 22, further comprising an encapsulant deposed on the chip carrier for encapsulating the first and the second chip modules and the first and the second bonding wires.

25. The multichip stacking structure of claim 22, wherein projections of the second chips are corresponding to positions of the first chips.

26. The multichip stacking structure of claim 22, further comprising a third chip module stacked on the second chip module.

27. The multichip stacking structure of claim 22, wherein the first and the second chip modules are electrically connected to the chip carrier by one of a wire bonding method and a reverse wire bond method.

28. The multichip stacking structure of claim 22, wherein the bottom chip of the second chip module is in one of a position corresponding to that of the top chip of the first chip module and a position horizontally deviated from that of the top chip of the first chip module for a distance.
